(19) United States
(12) Patent Application Publication
(10) Pub. No.: US 2024/0127730 A1
(43) Pub. Date: Apr. 18, 2024

(54) PATTERN DISPLAY DEVICE AND PATTERN DISPLAY METHOD

(71) Applicants: Interface Technology (ChengDu) Co., Ltd., Sichuan (CN); Interface Optoelectronics (ShenZhen) Co., Ltd., Guangdong (CN); Interface Optoelectronics (Wuxi) Co., Ltd., Jiangsu (CN); General Interface Solution Limited, Miaoli County (TW)

(72) Inventor: Hsuan-Yun LEE, Guangdong (CN)

(21) Appl. No.: 18/059,989

(22) Filed: Nov. 30, 2022

(30) Foreign Application Priority Data
Oct. 18, 2022 (CN) 202211272900.2

(51) Int. Cl. G09G 3/14; H01L 25/075

(52) U.S. Cl. CPC G09G 3/14; H01L 25/0753; G09G 2330/021

(57) ABSTRACT

A pattern display device includes a display device and a processor. A plurality of first areas include a plurality of first light emitting diodes, and a plurality of first terminals of the plurality of first light emitting diodes are coupled to each other. A plurality of second areas include a plurality of second light emitting diodes, and a plurality of second terminals of the plurality of second light emitting diodes are coupled to each other. A plurality of third areas include a plurality of third light emitting diodes, and a plurality of third terminals of the plurality of third areas are coupled to each other. During a first period, the first pattern area which is formed by the plurality of first areas and the plurality of second areas receives the first signal to display a first pattern.

### CROSS-REFERENCE TO RELATED APPLICATION

This application claims priority to China Application Serial Number 202211272900.2, filed Oct. 18, 2022, which is herein incorporated by reference in its entirety.

### BACKGROUND

### Field of Invention

The present invention relates to a display device and a display method. More particularly, the present invention relates to a pattern display device and a pattern display method.

### Description of Related Art

At present, the structure of the general micro light emitting diode display device (such as the Mini LED display or the Micro LED display) applied to the button is that each button must have a display (or a panel), and this display is covered with the micro light emitting diode (such as the Mini LED or the Micro LED).

However, to drive the above-mentioned display, each display must have a driver IC to drive each micro light emitting diode to emit light. Therefore, the system-side processor (MCU) must have a plurality of sets of transmission channels and signals to transmit images to each driver IC.

Furthermore, the driver IC is coupled to the positive and negative electrodes of each micro light emitting diode, and the processor needs to control whether each micro light emitting diode emits light through the driver IC.

### SUMMARY

The present disclosure provides a pattern display device. The pattern display device comprises a display device and a processor. The display device comprises a plurality of first areas, a plurality of second areas, and a plurality of third areas. The plurality of first areas comprise a plurality of first light emitting diodes, and a plurality of first terminals of the plurality of first light emitting diodes are coupled to each other. The plurality of second areas comprise a plurality of second light emitting diodes, and a plurality of second terminals of the plurality of second light emitting diodes are coupled to each other. A first pattern area is formed by the plurality of first areas and the plurality of second areas. The plurality of third areas comprise a plurality of third light emitting diodes, and a plurality of third terminals of the plurality of third areas are coupled to each other. A second pattern area is formed by the plurality of second areas and the plurality of third areas. The processor is configured to output a first signal. During a first period, the first pattern area which is formed by the plurality of first areas and the plurality of second areas receives the first signal to display a first pattern. During a second period, the second pattern area which is formed by the plurality of second areas and the plurality of third areas receives the first signal to display a second pattern.

The present disclosure provides a pattern display method. The pattern display method comprises the following steps: forming a first pattern area by a plurality of first areas of a display device and a plurality of second areas of the display device, wherein the plurality of first areas comprise a plurality of first light emitting diodes, wherein a plurality of first terminals of the plurality of first light emitting diodes are coupled to each other, wherein the plurality of second areas comprise a plurality of second light emitting diodes, wherein a plurality of second terminals of the plurality of second light emitting diodes are coupled to each other; forming a second pattern area by the plurality of second areas of the display device and a plurality of third areas of the display device, wherein the plurality of third areas comprise a plurality of third light emitting diodes, wherein a plurality of third terminals of the plurality of third areas are coupled to each other; outputting a first signal by a processor; during a first period, receiving the first signal to display a first pattern by the first pattern area which is formed by the plurality of first areas and the plurality of second areas; and during a second period, receiving the first signal to display a second pattern by the second pattern area which is formed by the plurality of second areas and the plurality of third areas.

Therefore, according to the technical content of the present disclosure, the pattern display device and the pattern display method of the present disclosure can form the plurality of fonts through the plurality of areas, so as to achieve the effect of displaying the plurality of fonts through the high signal and the low signal.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1A˜1C are block diagrams of a pattern display device according to one embodiment of the present disclosure.

FIGS. 2A˜2B are usage scenario diagrams of a pattern display device according to one embodiment of the present disclosure.

FIGS. 3A˜3C are schematic diagrams of a pattern display device according to one embodiment of the present disclosure.

FIG. 4 is a schematic flow diagram of a pattern display method according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The embodiments below are described in detail with the accompanying drawings, but the examples provided are not intended to limit the scope of the disclosure covered by the description. The structure and operation are not intended to limit the execution order. Any structure regrouped by elements, which has an equal effect, is covered by the scope of the present disclosure.

Various embodiments of the present technology are discussed in detail below with figures. It should be understood that the details should not limit the present disclosure. In other words, in some embodiments of the present disclosure, the details are not necessary. In addition, for simplification of figures, some known and commonly used structures and elements are illustrated simply in figures.

In the present disclosure, “connected” or “coupled” may refer to “electrically connected” or “electrically coupled.” “Connected” or “coupled” may also refer to operations or actions between two or more elements.

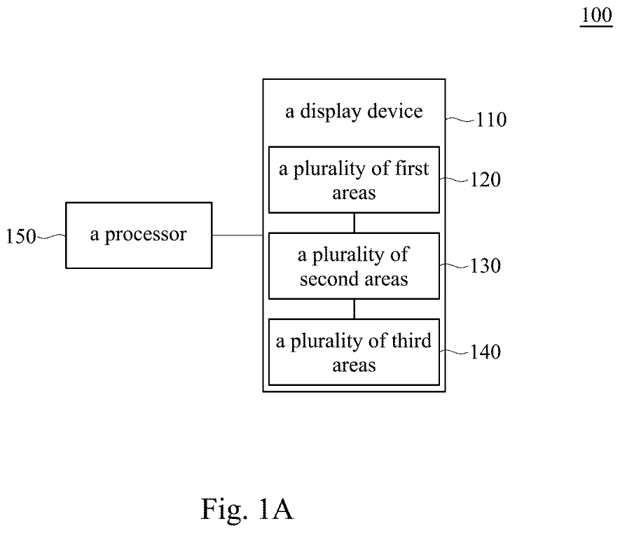

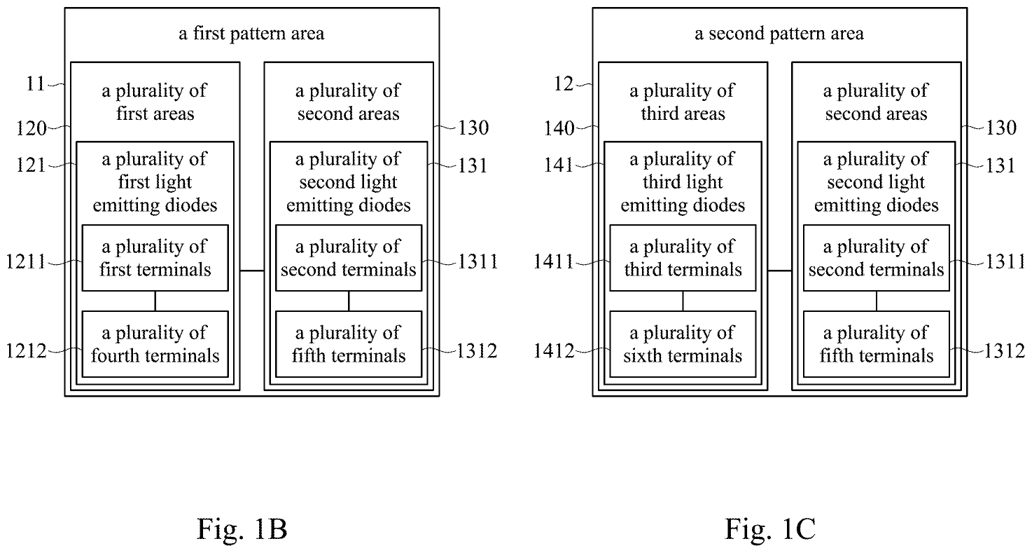

FIGS. 1A-1C are block diagrams of a pattern display device according to one embodiment of the present disclosure. Please refer to FIG. 1A, the pattern display device 100 includes a display device 110 and a processor 150. The display device 110 includes a plurality of first areas 120, a plurality of second areas 130, and a plurality of third areas 140. In connection relationship, the display device 110 is coupled to the processor 150.

In order to form the plurality of fonts through the plurality of areas, so as to achieve the effect of displaying the plurality of fonts through the high signal and the low signal, the present disclosure provides the pattern display device 100 as shown in FIG. 1A, and the related operations are described in detail as below.

Please refer to FIG. 1A and FIG. 1B, in one embodiment, the plurality of first areas 120 includes a plurality of first light emitting diodes 121, and a plurality of first terminals 1211 of the plurality of first light emitting diodes 121 are coupled to each other. In addition, in order to make the present disclosure easier to be understood, here is the circuit block diagram. For example, the plurality of first light emitting diodes 121 can be the Mini-LED or the Micro-LED, the plurality of first terminals 1211 can be the anode terminal or the cathode terminal, but the present disclosure is not limited to this embodiment. In some embodiments, the size of the Mini-LED can be 75˜300 μm, the size of the Micro-LED can be 100 μm or less than 75 μm, but the present disclosure is not limited to this embodiment. In some embodiments, the plurality of first terminals 1211 can be coupled to each other to form a first line, and the first line is configured to receive the high signal, the low signal or ground, but the present disclosure is not limited to this embodiment.

In one embodiment, a plurality of second areas 130 includes a plurality of second light emitting diodes 131, and a plurality of second terminals 1311 of the plurality of second light emitting diodes 131 are coupled to each other. In addition, in order to make the present disclosure easier to be understood, here is the circuit block diagram. For example, the plurality of second light emitting diodes 131 can be the Mini-LED or the Micro-LED, the plurality of second terminals 1311 can be the anode terminal or the cathode terminal, but the present disclosure is not limited to this embodiment. In some embodiments, the plurality of second terminals 1311 can be coupled to each other to form a second line, and the second line is configured to receive the high signal, the low signal or ground, but the present disclosure is not limited to this embodiment.

In one embodiment, the plurality of first areas 120 and the plurality of second areas 130 form a first pattern area 11. For example, the first pattern area 11 can be the font (or typeface) area with the shape “A”, “B”, “X” or “Y”, the first pattern area 11 can also be the area formed by the appearance of any national language, but the present disclosure is not limited to this embodiment.

Please refer to FIG. 1A and FIG. 1C, in one embodiment, the plurality of third areas 140 includes a plurality of third light emitting diodes 141, and a plurality of third terminals 1411 of the plurality of third light emitting diodes 141 are coupled to each other. In addition, in order to make the present disclosure easier to be understood, here is the circuit block diagram. For example, the plurality of third light emitting diodes 141 can be the Mini-LED or the Micro-LED, the plurality of third terminals 1411 can be the anode terminal or the cathode terminal, but the present disclosure is not limited to this embodiment. In some embodiments, the plurality of third terminals 1411 can be coupled to each other form a third line, and the third line is configured to receive the high signal, the low signal or ground, but the present disclosure is not limited to this embodiment.

In some embodiments, the plurality of first light emitting diodes 121, the plurality of second light emitting diodes 131, or the plurality of third light emitting diodes 141 can be bonded to the circuit board. The total number of the plurality of first light emitting diodes 121, the plurality of second light emitting diodes 131, and the plurality of third light emitting diodes 141 which are located on the display device 110 of the present disclosure is smaller than the number of light emitting diodes that covering the conventional display device. For example, the number of light emitting diodes that are covering the conventional display device can be 24×24, and the total number of the plurality of first light emitting diodes light emitting diodes 141 which are located on the display device 110 of the present disclosure can be smaller than 24×24. This effectively increases the yield of bonding the light emitting diodes to the circuit board process, but the present disclosure is not limited to this embodiment.

In one embodiment, the plurality of second areas 130 and the plurality of third areas 140 form a second pattern area 12. For example, the second pattern area 12 can be the font (or typeface) area with the shape “A”, “B”, “X” or “Y”, and the second pattern area 12 can also be the area formed by the appearance of any national language, but the present disclosure is not limited to this embodiment.

In one embodiment, the processor 150 (as shown in FIG. 1A) is configured to output a first signal. For example, the processor 150 can be a microcontroller unit, the first signal can be a high signal or a forward bias voltage for light emitting diodes (such as the Mini-LED or the Micro-LED), but the present disclosure is not limited to this embodiment.

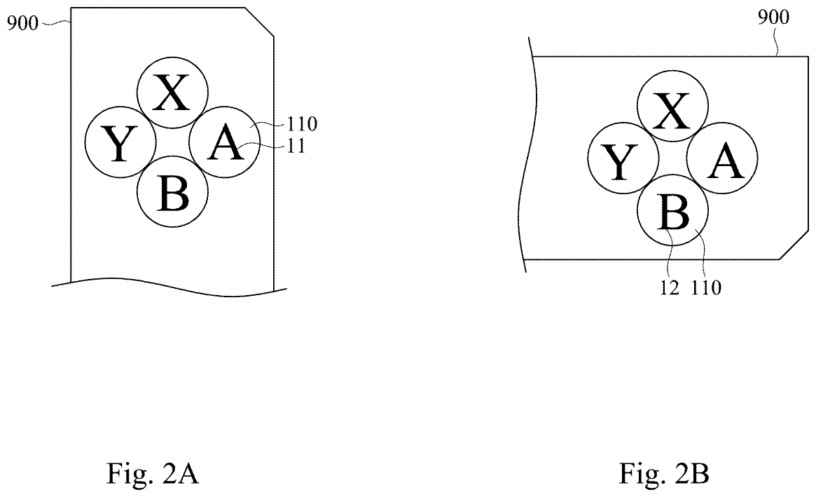

FIGS. 2A-2B are usage scenario diagrams of a pattern display device according to one embodiment of the present disclosure. Please refer to FIG. 2A and FIG. 2B, in some embodiments, the electronic device 900 can have the display device 110, the first pattern area 11 of the display device 110 can display the first pattern, and the second pattern area 12 of the display device 110 can display the second pattern. For example, the electronic device 900 of FIG. 2B is the result of rotating the electronic device 900 of FIG. 2A by 90 degrees, the first pattern area 11 can be the font (or typeface) area with the shape “A”, the second pattern area 12 can be the font (or typeface) area with the shape “B”, but the present disclosure is not limited to this embodiment. In some embodiments, the appearance of the display device 110 can be any shape, such as circle, square or triangle, but the present disclosure is not limited to this embodiment. In some embodiments, the first pattern area 11 can be the pattern area with various shapes, such as a flower, a triangle or a square, but the present disclosure is not limited to this embodiment. In some embodiments, the second pattern area 12 can be the pattern area with various shapes, such as a flower, a triangle or a square, but the present disclosure is not limited to this embodiment.

In some embodiments, the electronic device 900 can be a portable electronic device, an electronic game device or a smart electronic devices (such as smart watches, smart phones, or smart switches), but the present disclosure is not limited to this embodiment.

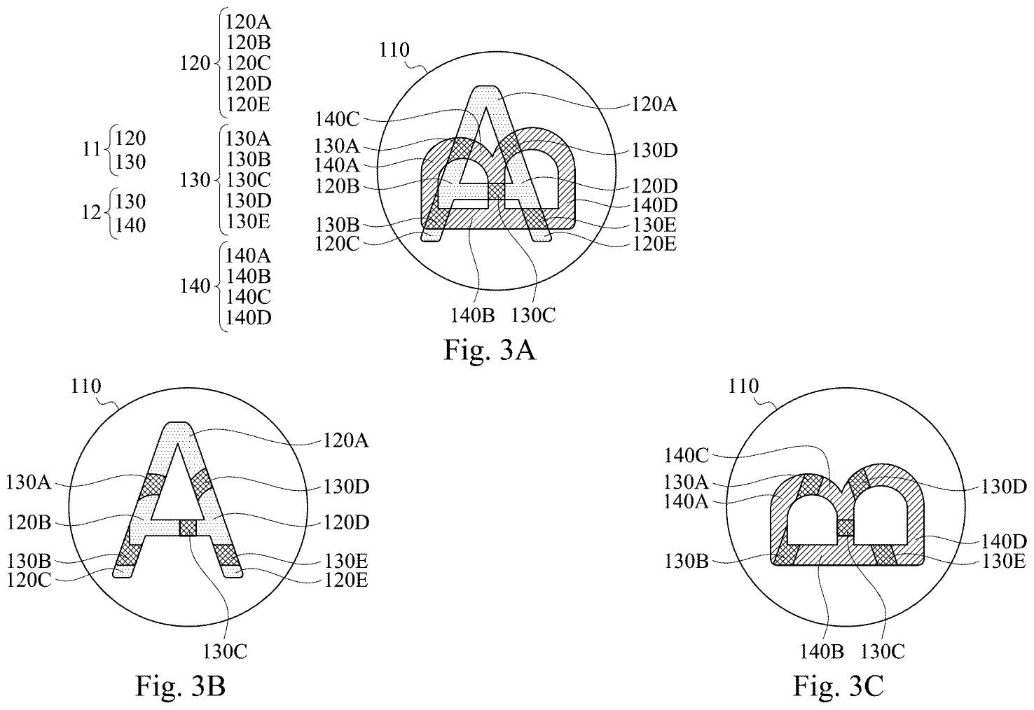

FIGS. 3A˜3C are schematic diagrams of a pattern display device according to one embodiment of the present disclosure. Please refer to FIG. 3A and FIG. 3B, in one embodiment, during a first period, the first pattern area 11 which is formed by the plurality of first areas 120 and the plurality of second areas 130 receives the first signal to display the first pattern. For example, the plurality of first areas 120 can be formed by the first area 120A-120E, and the plurality of second areas 130 can be formed by the second area 130A-130E. The first pattern area 11 can be the font (or typeface) area with the shape “A”, the first signal can be the high signal or the forward bias voltage for light emitting diodes (such as the Mini-LED or the Micro-LED), and the first pattern can be the font (or typeface) with the appearance of “A”, but the present disclosure is not limited to this embodiment.

In some embodiments, the first pattern area 11 can be formed by the plurality of Mini-LED or the plurality of Micro-LED, and the plurality of Mini-LED or the plurality of Micro-LED are arranged to form the font (or typeface) area with the shape “A”.

Please refer to FIG. 3A and FIG. 3C, in one embodiment, during the second period, the second pattern area 12 which is formed by the plurality of second areas 130 and the plurality of third areas 140 receives the first signal to display the second pattern. For example, the plurality of third areas 140 can be formed by the third area 140A-140D, the second pattern area 12 can be the font (or typeface) area with the shape “B”, and the second pattern can be the font (or typeface) area with the shape “B”, but the present disclosure is not limited to this embodiment.

In some embodiments, second pattern area 12 can be formed by the plurality of Mini-LED or the plurality of Micro-LED, and the plurality of Mini-LED or the plurality of Micro-LED are arranged to form the font (or typeface) area with the shape “B”.

In some embodiments, the plurality of first light emitting diodes 121, the plurality of second light emitting diodes 131, and the plurality of third light emitting diodes 141 on the first pattern area 11 and the second pattern area 12 of the present disclosure can receive directly the first signal from the processor 150 without passing through the driver IC, so it can effectively reduce the material cost of the driver IC and reduce the risk of bad bonding of the driver IC to the circuit board.

In some embodiments, the signal (such as the first signal) which is provided by the processor 150 is relatively simple, there is no need for a plurality of sets of transmission channels to provide the image signal of the entire display, which further reduces the cost of the processor 150 (that is, there is no need to use a high level processor), and reduce the time to transfer the images. In addition, it is not necessary to provide the image signal of the entire display in the present disclosure, and it is only necessary to change the level of the first signal which is received by the plurality of first light emitting diodes 121, the plurality of second light emitting diodes 131, and the plurality of third light emitting diodes 141 on the first pattern area 11 and the second pattern area 12, so the speed of the image change can be faster.

Furthermore, the total number of the plurality of first light emitting diodes 121, the plurality of second light emitting diodes 131, and the plurality of third light emitting diodes 141 can be reduced compared to the number of light emitting diodes of the conventional display device, and no the driver IC is required, so the pattern display device 100 of the present disclosure can effectively reduce the power consumption.

In some embodiments, the plurality of second areas 130 can be the overlapping areas of the first pattern area 11 and the second pattern area 12. In some embodiments, the plurality of first light emitting diodes 121 of the plurality of first areas 120, the plurality of first light emitting diodes 131 of the plurality of second areas 130, and the plurality of third light emitting diodes 141 of the plurality of third areas 140 can be the light emitting diodes (such as the Mini-LED or the Micro-LED) of the same type and color, but the present disclosure is not limited to this embodiment.

Please refer to FIG. 1B and FIG. 1C, in one embodiment, the plurality of first light emitting diodes 141 includes a plurality of fourth terminals 1212, and the plurality of fourth terminals 1212 are coupled to each other. The plurality of second light emitting diodes 131 includes a plurality of fifth terminals 1312, and the plurality of fifth terminals 1312 are coupled to each other. The plurality of third light emitting diodes 141 includes a plurality of sixth terminals 1412, and the plurality of sixth terminals 1412 are coupled to each other. For example, the plurality of fourth terminals 1212, the plurality of fifth terminals 1312, or the plurality of sixth terminals 1412 can be the anode terminal or the cathode terminal, but the present disclosure is not limited to this embodiment. In some embodiments, the plurality of fourth terminals 1212 can be coupled to each other to form a fourth line, and the fourth line are configured to receive the high signal, the low signal, or ground. The plurality of fifth terminals 1312 can be coupled to each other to form a fifth line, and the fifth line is configured to receive the high signal, the low signal, or ground. The plurality of sixth terminals 1412 can be coupled to each other to form a sixth line, and the sixth line is configured to receive the high signal, the low signal, or ground, but the present disclosure is not limited to this embodiment.

In one embodiment, the plurality of first terminals 1211 of the plurality of first light emitting diodes 121 are configured to receive the first signal. The plurality of second terminals 1311 of the plurality of second light emitting diodes 131 are configured to receive the first signal. The plurality of third terminals 1411 of the plurality of third light emitting diodes 141 are configured to receive the first signal. In one embodiment, the plurality of fourth terminals 1212 of the plurality of first light emitting diodes 121 are configured to receive the second signal. The plurality of fifth terminals 1312 of the plurality of second light emitting diodes 131 are configured to receive the second signal. The plurality of sixth terminals 1412 of the plurality of third light emitting diodes 141 are configured to receive the second signal. For example, when the first signal is the high signal, the second signal can be the low signal (such as ground), but the present disclosure is not limited to this embodiment.

In one embodiment, the plurality of first terminals 1211 includes the plurality of first anode terminals. The plurality of second terminals 1311 includes the plurality of second anode terminals. The plurality of third terminals 1411 includes the plurality of third anode terminals. The plurality of fourth terminals 1212 includes the plurality of first cathode terminals. The plurality of fifth terminals 1312 includes the plurality of second cathode terminals. The plurality of sixth terminals 1412 includes the plurality of third cathode terminals. For example, the plurality of first terminals 1211, the plurality of second terminals 1311, and the plurality of third terminals 1411 can be the anode terminal. The plurality of fourth terminals 1212, the plurality of fifth terminals 1312, and the plurality of sixth terminals 1412 can be the cathode terminal, but the present disclosure is not limited to this embodiment.

In one embodiment, the first signal includes the forward signal, and the second signal includes the ground signal. For example, the first signal can be the forward voltage of the plurality of first light emitting diodes 121, the plurality of second light emitting diodes 131, and the plurality of third light emitting diodes 141. The second signal can be grounded (such as the voltage is zero), but the present disclosure is not limited to this embodiment.

In one embodiment, the plurality of first terminals 1211 of the plurality of first light emitting diodes 121 are configured to receive the second signal. The plurality of second terminals 1311 of the plurality of second light emitting diodes 131 are configured to receive the second signal. The plurality of third terminals 1411 of the plurality of third light emitting diodes 1412 are configured to receive the second signal. In one embodiment, the plurality of fourth terminals 1212 of the plurality of first light emitting diodes 121 are configured to receive the first signal. The plurality of fifth terminals 1312 of the plurality of second light emitting diodes 131 are configured to receive first signal. The plurality of sixth terminals 1412 of the plurality of third light emitting diodes 141 are configured to receive the first signal. For example, when the second signal is the high signal, the first signal can be the low signal (such as ground), but the present disclosure is not limited to this embodiment.

In one embodiment, the plurality of first terminals 1211 includes the plurality of first cathode terminals. The plurality of second terminals 1311 includes the plurality of second cathode terminals. The plurality of third terminals 1411 includes the plurality of third cathode terminals. The plurality of fourth terminals 1212 includes the plurality of first anode terminals. The plurality of fifth terminals 1312 includes the plurality of second anode terminals. The plurality of sixth terminals 1412 includes the plurality of third anode terminals. For example, the plurality of first terminals 1211, the plurality of second terminals 1311, and the plurality of third terminals 1411 can be the cathode terminal. The plurality of fourth terminals 1212, the plurality of fifth terminals 1312, and the plurality of sixth terminals 1412 can be the anode terminal, but the present disclosure is not limited to this embodiment.

In one embodiment, the first signal includes the forward signal, and the second signal includes the ground signal. For example, the first signal can be the forward signal of the plurality of first light emitting diodes 121, the plurality of second light emitting diodes 131, and the plurality of third light emitting diodes 141. The second signal can be grounded (such as the voltage is zero), but the present disclosure is not limited to this embodiment.

In some embodiments, the gap between the light emitting diodes of the plurality of first light emitting diodes 121, the plurality of second light emitting diodes 131, and the plurality of third light emitting diodes 141 in the present disclosure can be 3 μm˜500 μm, but the present disclosure is not limited to this embodiment.

In some embodiments, the display device 110 of the present disclosure can further include a plurality of areas and a plurality of light emitting diodes to form a third pattern area and a fourth pattern area, and the third pattern area can display the third pattern, and the fourth pattern area can display the fourth pattern. For example, during the different periods, the display device 110 can display the first pattern 11 (such as “A” font), second pattern 12 (such as “B” font), the third pattern (such as “C” font), or the fourth pattern (such as “D” font). The related structures and operations of the third pattern and the fourth pattern are similar to the structure and operation logic of the first pattern 11 and the second pattern 12, and the descriptions regarding the related structures and operations of the third pattern and the fourth pattern in the display device 110 will be omitted herein for the sake of brevity.

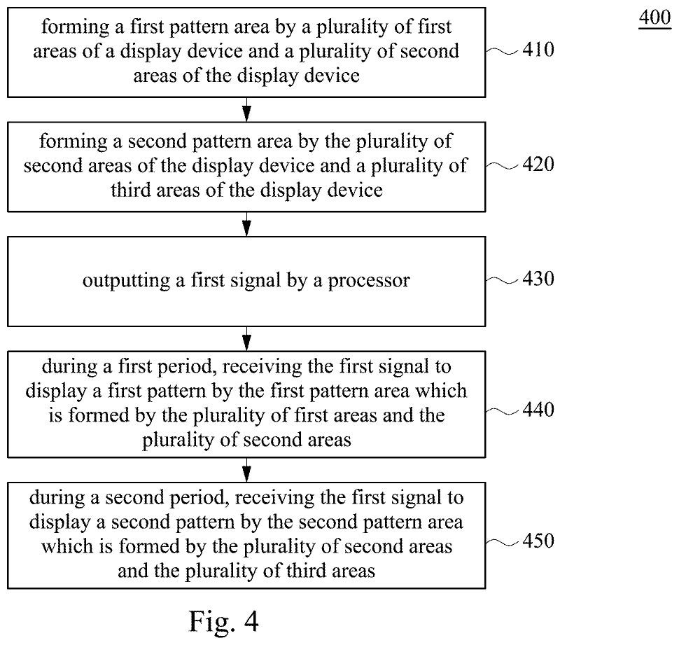

FIG. 4 is a schematic flow diagram of a pattern display method according to one embodiment of the present disclosure. In order to make the pattern display method 400 of FIG. 4 easier to be understood please refer to FIG. 1A to FIG. 4. The steps of the pattern display method 400 of FIG. 4 are detailed as follows.

Step 410, forming a first pattern area by a plurality of first areas of a display device and a plurality of second areas of the display device. Please refer to FIG. 1A, FIG. 1B, and step 410, in one embodiment, the first pattern area 11 can be formed by the plurality of first areas 120 of the display device 110 and the plurality of second areas 130 of the display device 110. The plurality of first areas 120 includes the plurality of first light emitting diodes 121, and the plurality of first terminals 1211 of the plurality of first light emitting diodes 121 are coupled to each other. The plurality of second areas 130 includes the plurality of second light emitting diodes 131, and the plurality of second terminals 1311 of the plurality of second light emitting diodes 131 are coupled to each other. For example, the operations of the pattern display method 400 are similar to the operations of the pattern display device 100 of FIG. 1A, and the descriptions regarding the other operations of the pattern display method 400 will be omitted herein for the sake of brevity.

Step 420, forming a second pattern area by the plurality of second areas of the display device and a plurality of third areas of the display device. Please refer to FIG. 1A, FIG. 1C, and step 420, in one embodiment, the second pattern area 12 can be formed by the plurality of second areas 130 of the display device 110 and the plurality of third areas 140 of the display device 110. The plurality of third areas 140 includes the plurality of third light emitting diodes 141, and the plurality of third terminals 1411 of the plurality of third light emitting diodes 141 are coupled to each other. For example, the operations of the pattern display method 400 are similar to the operations of the pattern display device 100 of FIG. 1A, and the descriptions regarding the other operations of the pattern display method 400 will be omitted herein for the sake of brevity.

Step 430, outputting a first signal by a processor. Please refer to FIG. 1A and step 430, in one embodiment, the first signal can be outputted by a processor 900. For example, the operations of the pattern display method 400 are similar to the operations of the pattern display device 100 of FIG. 1A, and the descriptions regarding the other operations of the pattern display method 400 will be omitted herein for the sake of brevity.

Step 440, during a first period, receiving the first signal to display a first pattern by the first pattern area which is formed by the plurality of first areas and the plurality of second areas. Please refer to FIG. 3A, FIG. 3B, and step 440, in one embodiment, receiving the first signal to display a first pattern by the first pattern area 11 which is formed by the plurality of first areas 120 and the plurality of second areas 130. For example, the operations of the pattern display method 400 are similar to the operations of the pattern display device 100 of FIG. 1A, and the descriptions regarding the other operations of the pattern display method 400 will be omitted herein for the sake of brevity.

Step 450, during a second period, receiving the first signal to display a second pattern by the second pattern area which is formed by the plurality of second areas and the plurality of third areas. Please refer to FIG. 3A, FIG. 3C, and step 450, in one embodiment, receiving the first signal to display the second pattern by the second pattern area 12 which is formed by the plurality of second areas 130 and the plurality of third areas 140. For example, the operations of the pattern display method 400 are similar to the operations of the pattern display device 100 of FIG. 1A, and the descriptions regarding the other operations of the pattern display method 400 will be omitted herein for the sake of brevity.

Please refer to FIG. 1B, FIG. 1C, and FIG. 4, in one embodiment, the plurality of first light emitting diodes 141 includes the plurality of fourth terminals 1212, and the plurality of fourth terminals 1212 are coupled to each other. The plurality of second light emitting diodes 131 includes the plurality of fifth terminals 1312, and the plurality of fifth terminals 1312 are coupled to each other. The plurality of third light emitting diodes 141 includes the plurality of sixth terminals 1412, and the plurality of sixth terminals 1412 are coupled to each other. In some embodiments, the plurality of fourth terminals 1212 can be coupled to each other to form a fourth line, and the fourth line are configured to receive the high signal, the low signal, or ground. The plurality of fifth terminals 1312 can be coupled to each other to form a fifth line, and the fifth line is configured to receive the high signal, the low signal, or ground. The plurality of sixth terminals 1412 can be coupled to each other to form a sixth line, and the sixth line is configured to receive the high signal, the low signal, or ground, but the present disclosure is not limited to this embodiment. For example, the operations of the pattern display method 400 are similar to the operations of the pattern display device 100 of FIG. 1A, and the descriptions regarding the other operations of the pattern display method 400 will be omitted herein for the sake of brevity.

In one embodiment, the plurality of first terminals 1211 of the plurality of first light emitting diodes 121 are configured to receive the first signal. The plurality of second terminals 1311 of the plurality of second light emitting diodes 131 are configured to receive the first signal. The plurality of third terminals 1411 of the plurality of third light emitting diodes 141 are configured to receive the first signal. In one embodiment, the plurality of fourth terminals 1212 of the plurality of first light emitting diodes 121 are configured to receive the second signal. The plurality of fifth terminals 1312 of the plurality of second light emitting diodes 131 are configured to receive the second signal. The plurality of sixth terminals 1412 of the plurality of third light emitting diodes 141 are configured to receive the second signal. For example, the operations of the pattern display method 400 are similar to the operations of the pattern display device 100 of FIG. 1A, and the descriptions regarding the other operations of the pattern display method 400 will be omitted herein for the sake of brevity.

In one embodiment, the plurality of first terminals 1211 includes the plurality of first anode terminals. The plurality of second terminals 1311 includes the plurality of second anode terminals. The plurality of third terminals 1411 includes the plurality of third anode terminals. The plurality of fourth terminals 1212 includes the plurality of first cathode terminals. The plurality of fifth terminals 1312 includes the plurality of second cathode terminals. The plurality of sixth terminals 1412 includes the plurality of third cathode terminals. For example, the operations of the pattern display method 400 are similar to the operations of the pattern display device 100 of FIG. 1A, and the descriptions regarding the other operations of the pattern display method 400 will be omitted herein for the sake of brevity.

In one embodiment, the first signal includes the forward signal, and the second signal includes the ground signal. For example, the operations of the pattern display method 400 are similar to the operations of the pattern display device 100 of FIG. 1A, and the descriptions regarding the other operations of the pattern display method 400 will be omitted herein for the sake of brevity.

In one embodiment, the plurality of first terminals 1211 of the plurality of first light emitting diodes 121 are configured to receive the second signal. The plurality of second terminals 1311 of the plurality of second light emitting diodes 131 are configured to receive the second signal. The plurality of third terminals 1411 of the plurality of third light emitting diodes 1412 are configured to receive the second signal. In one embodiment, the plurality of fourth terminals 1212 of the plurality of first light emitting diodes 121 are configured to receive the first signal. The plurality of fifth terminals 1312 of the plurality of second light emitting diodes 131 are configured to receive first signal. The plurality of sixth terminals 1412 of the plurality of third light emitting diodes 141 are configured to receive the first signal. For example, the operations of the pattern display method 400 are similar to the operations of the pattern display device 100 of FIG. 1A, and the descriptions regarding the other operations of the pattern display method 400 will be omitted herein for the sake of brevity.

In one embodiment, the plurality of first terminals 1211 includes the plurality of first cathode terminals. The plurality of second terminals 1311 includes the plurality of second cathode terminals. The plurality of third terminals 1411 includes the plurality of third cathode terminals. The plurality of fourth terminals 1212 includes the plurality of first anode terminals. The plurality of fifth terminals 1312 includes the plurality of second anode terminals. The plurality of sixth terminals 1412 includes the plurality of third anode terminals. For example, the operations of the pattern display method 400 are similar to the operations of the pattern display device 100 of FIG. 1A, and the descriptions regarding the other operations of the pattern display method 400 will be omitted herein for the sake of brevity.

In one embodiment, the first signal includes the forward signal, and the second signal includes the ground signal. For example, the operations of the pattern display method 400 are similar to the operations of the pattern display device 100 of FIG. 1A, and the descriptions regarding the other operations of the pattern display method 400 will be omitted herein for the sake of brevity.

It can be seen from the above embodiments of the present disclosure that the application of the present disclosure has the following advantages. The pattern display device and the pattern display method shown in the embodiment of the present disclosure can form the plurality of fonts through the plurality of areas, so as to achieve the effect of displaying the plurality of fonts through the high signal and the low signal.

In addition, the total number of the plurality of first light emitting diodes light emitting diodes 141 which are located on the display device 110 of the present disclosure is smaller than the number of light emitting diodes that covering the conventional display device. In this way, the effect of effectively increasing the yield of bonding the light emitting diodes to the circuit board process.

Then, the plurality of first light emitting diodes 121, the plurality of second light emitting diodes 131, and the plurality of third light emitting diodes 141 on the first pattern area 11 and the second pattern area 12 of the present disclosure can receive directly the first signal from the processor 150 without passing through the driver IC, so it can effectively reduce the material cost of the driver IC and reduce the risk of bad bonding of the driver IC to the circuit board.

Moreover, the signal (such as the first signal) which is provided by the processor 150 is relatively simple, there is no need for the plurality of sets of transmission channels to provide the image signal of the entire display, which further reduces the cost of the processor 150 (that is, there is no need to use a high level processor), and reduce the time to transfer the images. In addition, it is not necessary to provide the image signal of the entire display in the present disclosure, and it is only necessary to change the level of the first signal which is received by the plurality of first light emitting diodes 121, the plurality of second light emitting diodes 131, and the plurality of third light emitting diodes 141 on the first pattern area 11 and the second pattern area 12, so it can achieve the effect that the speed of the image change can be faster.

Furthermore, the total number of the plurality of first light emitting diodes light emitting diodes 141 can be reduced compared to the number of light emitting diodes of the conventional display device, and no the driver IC is required, so the pattern display device 100 of the present disclosure can effectively reduce the power consumption.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A pattern display device, comprising:
a display device, comprising:
a plurality of first areas, comprising a plurality of first light emitting diodes, wherein a plurality of first terminals of the plurality of first light emitting diodes are coupled to each other;
a plurality of second areas, comprising a plurality of second light emitting diodes, wherein a plurality of second terminals of the plurality of second light emitting diodes are coupled to each other, wherein a first pattern area is formed by the plurality of first areas and the plurality of second areas; and
a plurality of third areas, comprising a plurality of third light emitting diodes, wherein a plurality of third terminals of the plurality of third areas are coupled to each other, wherein a second pattern area is formed by the plurality of second areas and the plurality of third areas; and
a processor, configured to output a first signal, wherein during a first period, the first pattern area which is formed by the plurality of first areas and the plurality of second areas receives the first signal to display a first pattern, wherein during a second period, the second pattern area which is formed by the plurality of second areas and the plurality of third areas receives the first signal to display a second pattern;
wherein along a first direction, one of the plurality of first areas has a first length, one of the plurality of second areas has a second length, and another of the plurality of first areas has a third length;
wherein the first length is greater than the second length, the first length is greater than the third length, and the second length is greater than the third length;
wherein the one of the plurality of first areas is an overlapping area of the first pattern area and the second pattern area;
wherein the one of the plurality of first areas is on first side of the one of the plurality of second areas;
wherein the another of the plurality of first areas is on second side of the one of the plurality of second areas;
wherein the first side and the second side are opposite to each other along the first direction.

2. The pattern display device of claim 1, wherein the plurality of first light emitting diodes comprise a plurality of fourth terminals, and the plurality of fourth terminals are coupled to each other, wherein the plurality of second light emitting diodes comprise a plurality of fifth terminals, and the plurality of fifth terminals are coupled to each other, wherein the plurality of third areas comprise a plurality of sixth terminals, and the plurality of sixth terminals are coupled to each other.

3. The pattern display device of claim 2, wherein the plurality of first terminals of the plurality of first light emitting diodes are configured to receive the first signal, wherein the plurality of second terminals of the plurality of second light emitting diodes are configured to receive the first signal, wherein the plurality of third terminals of the plurality of third areas are configured to receive the first signal.

4. The pattern display device of claim 3, wherein the plurality of fourth terminals of the plurality of first light emitting diodes are configured to receive a second signal, wherein the plurality of fifth terminals of the plurality of second light emitting diodes are configured to receive the second signal, wherein the plurality of sixth terminals of the plurality of third areas are configured to receive the second signal.

5. The pattern display device of claim 4, wherein the plurality of first terminals comprise a plurality of first anode terminals, the plurality of second terminals comprise a plurality of second anode terminals, and the plurality of third terminals comprise a plurality of third anode terminals, wherein the plurality of fourth terminals comprise a plurality of first cathode terminals, the plurality of fifth terminals comprise a plurality of second cathode terminals, and the plurality of sixth terminals comprise a plurality of third cathode terminals.

6. The pattern display device of claim 5, wherein the first signal comprises a forward signal, wherein the second signal comprises a ground signal.

7. The pattern display device of claim 2, wherein the plurality of first terminals of the plurality of first light emitting diodes are configured to receive a second signal, wherein the plurality of second terminals of the plurality of second light emitting diodes are configured to receive the second signal, wherein the plurality of third terminals of the plurality of third areas are configured to receive the second signal.

8. The pattern display device of claim 7, wherein the plurality of fourth terminals of the plurality of first light emitting diodes are configured to receive the first signal, wherein the plurality of fifth terminals of the plurality of second light emitting diodes are configured to receive the first signal, wherein the plurality of sixth terminals of the plurality of third areas are configured to receive the first signal.

9. The pattern display device of the claim 8, wherein the plurality of first terminals comprise a plurality of first cathode terminals, the plurality of second terminals comprise a plurality of second cathode terminals, and the plurality of third terminals comprise a plurality of third cathode terminals, wherein the plurality of fourth terminals comprise a plurality of first anode terminals, the plurality of fifth terminals comprise a plurality of second anode terminals, and the plurality of sixth terminals comprise a plurality of third anode terminals.

10. The pattern display device of claim 9, wherein the first signal comprises a forward signal, wherein the second signal comprises a ground signal.

11. A pattern display method, comprising:
forming a first pattern area by a plurality of first areas of a display device and a plurality of second areas of the display device, wherein the plurality of first areas comprise a plurality of first light emitting diodes, wherein a plurality of first terminals of the plurality of first light emitting diodes are coupled to each other, wherein the plurality of second areas comprise a plurality of second light emitting diodes, wherein a plurality of second terminals of the plurality of second light emitting diodes are coupled to each other;
forming a second pattern area by the plurality of second areas of the display device and a plurality of third areas of the display device, wherein the plurality of third areas comprise a plurality of third light emitting diodes, wherein a plurality of third terminals of the plurality of third areas are coupled to each other;
outputting a first signal by a processor;
during a first period, receiving the first signal to display a first pattern by the first pattern area which is formed by the plurality of first areas and the plurality of second areas; and
during a second period, receiving the first signal to display a second pattern by the second pattern area which is formed by the plurality of second areas and the plurality of third areas;
wherein the processor directly connects to each of the plurality of first light emitting diodes, the plurality of second light emitting diodes, and the plurality of third light emitting diodes.

12. The pattern display method of claim 11, wherein the plurality of first light emitting diodes comprise a plurality of fourth terminals, and the plurality of fourth terminals are coupled to each other, wherein the plurality of second light emitting diodes comprise a plurality of fifth terminals, and the plurality of fifth terminals are coupled to each other, wherein the plurality of third areas comprise a plurality of sixth terminals, and the plurality of sixth terminals are coupled to each other.

13. The pattern display method of claim 12, wherein the plurality of first terminals of the plurality of first light emitting diodes are configured to receive the first signal, wherein the plurality of second terminals of the plurality of second light emitting diodes are configured to receive the first signal, wherein the plurality of third terminals of the plurality of third areas are configured to receive the first signal.

14. The pattern display method of claim 13, wherein the plurality of fourth terminals of the plurality of first light emitting diodes are configured to receive a second signal, wherein the plurality of fifth terminals of the plurality of second light emitting diodes are configured to receive the second signal, wherein the plurality of sixth terminals of the plurality of third areas are configured to receive the second signal.

15. The pattern display method of claim 14, wherein the plurality of first terminals comprise a plurality of first anode terminals, the plurality of second terminals comprise a plurality of second anode terminals, and the plurality of third terminals comprise a plurality of third anode terminals, wherein the plurality of fourth terminals comprise a plurality of first cathode terminals, the plurality of fifth terminals comprise a plurality of second cathode terminals, and the plurality of sixth terminals comprise a plurality of third cathode terminals.

16. The pattern display method of claim 15, wherein the first signal comprises a forward signal, wherein the second signal comprises a ground signal.

17. The pattern display method of claim 12, wherein the plurality of first terminals of the plurality of first light emitting diodes are configured to receive a second signal, wherein the plurality of second terminals of the plurality of second light emitting diodes are configured to receive the second signal, wherein the plurality of third terminals of the plurality of third areas are configured to receive the second signal.

18. The pattern display method of claim 17, wherein the plurality of fourth terminals of the plurality of first light emitting diodes are configured to receive the first signal, wherein the plurality of fifth terminals of the plurality of second light emitting diodes are configured to receive the first signal, wherein the plurality of sixth terminals of the plurality of third areas are configured to receive the first signal.

19. The pattern display method of claim 18, wherein the plurality of first terminals comprise a plurality of first cathode terminals, the plurality of second terminals comprise a plurality of second cathode terminals, and the plurality of third terminals comprise a plurality of third cathode terminals, wherein the plurality of fourth terminals comprise a plurality of first anode terminals, the plurality of fifth terminals comprise a plurality of second anode terminals, and the plurality of sixth terminals comprise a plurality of third anode terminals.

20. The pattern display method of claim 19, wherein the first signal comprises a forward signal, wherein the second signal comprises a ground signal.
